(19) United States
(12) Patent Application Publication
(10) Pub. No.: US 2020/0313067 A1
(43) Pub. Date: Oct. 1, 2020

(54) MULTILAYER PIEZOELECTRIC ELEMENT

(71) Applicant: TDK CORPORATION, Tokyo (JP)

(72) Inventors: Makoto ISHIZAKI, Tokyo (JP); Masaharu HIRAKAWA, Tokyo (JP)

(73) Assignee: TDK CORPORATION, Tokyo (JP)

(21) Appl. No.: 16/830,374

(22) Filed: Mar. 26, 2020

(30) Foreign Application Priority Data
Mar. 28, 2019 (JP) 2019-064818

(51) Int. Cl. H01L 41/083; H01L 41/047; H01L 41/297; H01L 41/273

(52) U.S. Cl. CPC H01L 41/083; H01L 41/0472; H01L 41/273; H01L 41/297; H01L 41/0477

(57) ABSTRACT

A multilayer piezoelectric element includes a laminated body and a lateral electrode. The laminated body includes a piezoelectric layer and an internal electrode layer. The piezoelectric layer is formed along a plane including a first axis and a second axis perpendicular to each other. The internal electrode layer is laminated on the piezoelectric layer. The internal electrode layer has a leading portion exposed to the lateral surface of the laminated body and is electrically connected with the lateral electrode via the leading portion. A dummy electrode layer is formed with a gap to surround the internal electrode layer excluding the leading portion on the plane of the piezoelectric layer. The dummy electrode layer is composed of a material whose thermal shrinkage start temperature is higher than that of a conductive metal constituting the internal electrode layer.

### BACKGROUND OF THE INVENTION

The present invention relates to a multilayer piezoelectric element.

Multilayer piezoelectric elements have a structure in which internal electrodes and piezoelectric layers are laminated and can increase displacement amount and driving force per unit volume compared to non-multilayer piezoelectric elements. To prevent short circuit by migration between internal electrode layers, it is normal for the multilayer piezoelectric elements that a lamination area of the internal electrode layers is smaller than that of the piezoelectric layers. In such a multilayer structure, however, generated is a shrinkage difference between a portion on which the internal electrode layers are present and a portion on which the internal electrode layers are absent, and the laminated body may thereby deform or have cracks.

In particular, the multilayer piezoelectric elements have been recently demanded for thinner or larger element bodies. When the element bodies are thinner or larger, they are easy to deform, and it is more difficult to prevent cracks.

Incidentally, Patent Document 1 discloses a technique of preventing the spread of cracks by increasing the Pd content at the end of the internal electrode layer composed Ag—Pd alloy. However, the technique disclosed by Patent Document 1 is hard to prevent the deformation of the element body.

Patent Document 1: JP2014072357 (A)

### BRIEF SUMMARY OF INVENTION

The present invention has been achieved under such circumstances. It is an object of the invention to provide a multilayer piezoelectric element capable of preventing deformation of an element body.

To achieve the above object, a multilayer piezoelectric element according to the present invention includes:

a laminated body including:
a piezoelectric layer formed along a plane including a first axis and a second axis perpendicular to each other; and
an internal electrode layer laminated on the piezoelectric layer; and

a lateral electrode formed on a lateral surface of the laminated body perpendicular to the first axis,

wherein the internal electrode layer has a leading portion exposed to the lateral surface of the laminated body and is electrically connected with the lateral electrode via the leading portion,

wherein a dummy electrode layer is formed with a gap to surround the internal electrode layer excluding the leading portion on the plane of the piezoelectric layer, and

wherein the dummy electrode layer is composed of a material whose thermal shrinkage start temperature is higher than that of a conductive metal constituting the internal electrode layer.

In the multilayer piezoelectric element according to the present invention, a dummy electrode layer is formed in the outer circumference of the internal electrode layer, and this dummy electrode layer is composed of a material whose thermal shrinkage start temperature is higher than that of a conductive metal constituting the internal electrode layer. In this structure, the present invention can have no sintered spots in the outer side and the inner side of the laminated body and prevent the deformation of the laminated body and the generation of cracks. Thus, even if each layer constituting the laminated body is thinner or larger, it is possible to obtain a multilayer piezoelectric element having a small deformation of the laminated body and exhibiting a high piezoelectric constant.

Preferably, the dummy electrode layer is composed of a conductive metal whose composition is different from that of the conductive metal constituting the internal electrode layer.

Preferably, the dummy electrode layer is composed of a material whose thermal shrinkage start temperature is higher than that of the conductive metal constituting the internal electrode layer by 50° C. or more and 280° C. or less.

Preferably, multiple pores are formed in the piezoelectric layer located in the gap between the internal electrode layer and the dummy electrode layer. The present invention has the pores and can thereby reduce the inner stress of the laminated body and further effectively prevent the deformation of the laminated body and the generation of cracks. Due to the pores, the composition of the piezoelectric layer can also be prevented from changing. Thus, even if each layer constituting the laminated body is thinner or larger, it is possible to obtain a multilayer piezoelectric element having a small deformation of the laminated body and exhibiting a high piezoelectric constant.

Preferably, the pores have an average size of 0.05 μm or more and 0.2 μm or less.

Preferably, the piezoelectric layer located in the gap has a pore rate of 3% or more and 20% or less.

Preferably, the gap has a width of 0.05 mm or more and 0.3 mm or less.

The multilayer piezoelectric element according to the present invention can be utilized as a conversion element from electrical energy to mechanical energy. For example, the multilayer piezoelectric element according to the present invention is applicable to piezoelectric actuators, piezoelectric buzzers, piezoelectric sounders, ultrasonic motors, speakers, etc. and is particularly favorably utilized as piezoelectric actuators. Specifically, the piezoelectric actuators are utilized for haptic devices, lens driving, HDD head driving, inkjet printer head driving, fuel injection valve driving, etc.

### BRIEF DESCRIPTION OF DRAWINGS

FIG. 1 is a schematic perspective view illustrating a multilayer piezoelectric element according to an embodiment of the present invention.

FIG. 2 is a schematic cross-sectional view cut along the II-II line shown in FIG. 1.

FIG. 3 is a schematic cross-sectional view cut along the line shown in FIG. 1.

FIG. 4A is a plane view illustrating a first electrode pattern contained in the multilayer piezoelectric element shown in FIG. 1.

FIG. 4B is a plane view illustrating a second electrode pattern contained in the multilayer piezoelectric element shown in FIG. 1.

FIG. 5 is an exploded perspective view of the multilayer piezoelectric element shown in FIG. 1.

FIG. 6A is a schematic cross-sectional view of a multilayer piezoelectric element according to another embodiment.

FIG. 6B is a schematically enlarged cross-sectional view of the region VIB shown in FIG. 6A.

### DETAILED DESCRIPTION OF INVENTION

Hereinafter, the present invention is explained based on embodiments shown in the figures.

### First Embodiment

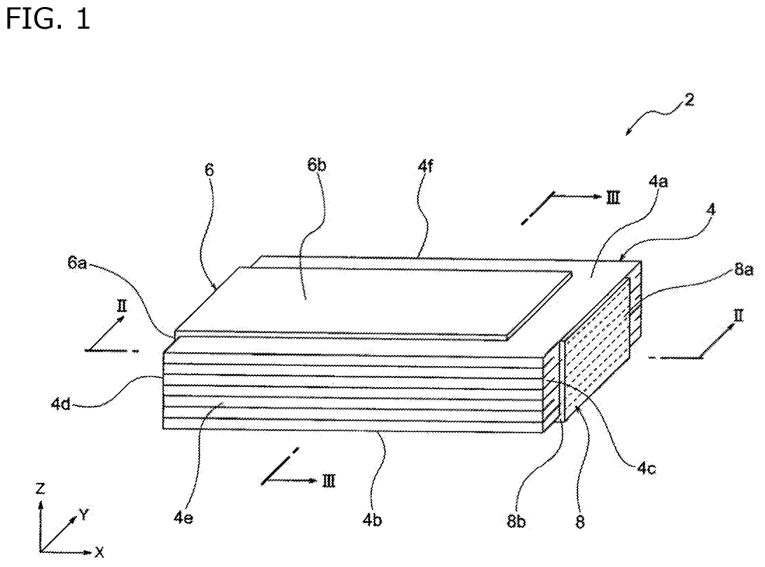

FIG. 1 is a schematic perspective view of a multilayer piezoelectric element 2 according to the present embodiment. As shown in FIG. 1, the multilayer piezoelectric element 2 includes a laminated body 4, a first external electrode 6, and a second external electrode 8.

The laminated body 4 has a substantially rectangular parallelepiped shape and has a front surface 4a and a back surface 4b substantially perpendicular to the Z-axis direction, lateral surfaces 4c and 4d substantially perpendicular to the X-axis (first axis) direction, and lateral surfaces 4e and 4f substantially perpendicular to the Y-axis (second axis) direction. Incidentally, insulating protect layers (not illustrated) may be formed on the lateral surfaces 4c-4f of the laminated body 4 excluding areas on which the external electrodes 6 and 8 are formed. In the figures, the X-axis, the Y-axis, and the Z-axis are substantially perpendicular to each other.

The first external electrode 6 has a first lateral part 6a formed along the lateral surface 4d of the laminated body 4 and a first surface part 6b formed along the front surface 4a of the laminated body 4. The first lateral part 6a and the first surface part 6b have a substantially rectangular shape and are connected with each other at their intersection. Incidentally, the first lateral part 6a and the first surface part 6b are illustrated separately in the figures, but are actually formed integrally.

The second external electrode 8 has a second lateral part 8a formed along the lateral surface 4c of the laminated body 4 and a second surface part 8b formed along the back surface 4b of the laminated body 4. As with the first external electrode 6, the second lateral part 8a and the second surface part 8b have a substantially rectangular shape and are connected with each other to be formed integrally at their intersection. As shown in FIG. 1, the first surface part 6b and the second surface part 8b are smaller than a plane of the laminated body 4 perpendicular to the Z-axis direction (the front surface 4a or the back surface 4b of the laminated body 4), and the first external electrode 6 and the second external electrode 8 are insulated with each other.

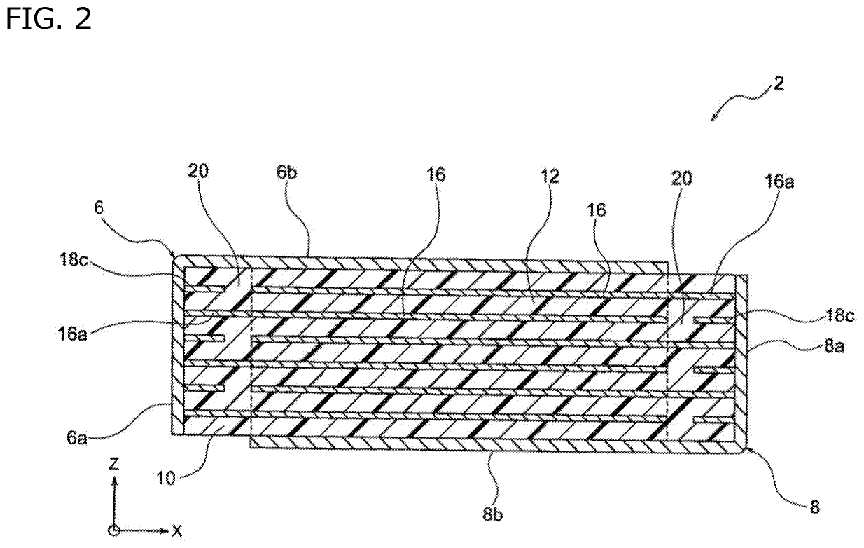

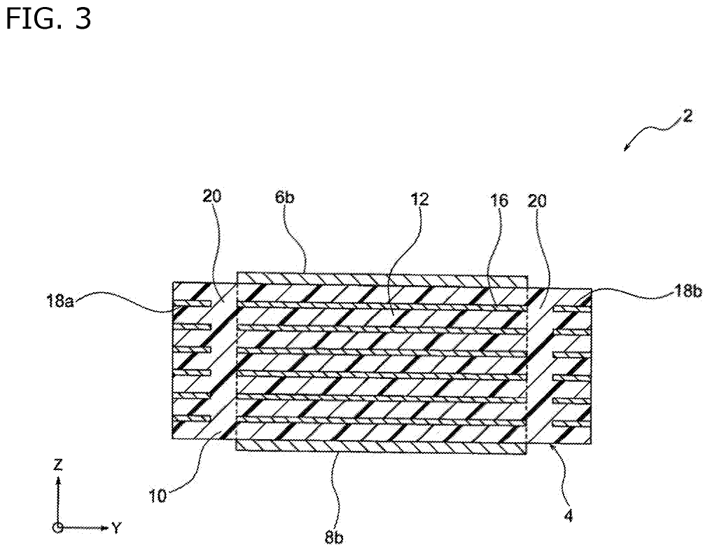

As shown in FIG. 2 and FIG. 3, the laminated body 4 has an internal structure in which piezoelectric layers 10 and internal electrode layers 16 are alternately laminated in the lamination direction (Z-axis direction). The internal electrode layers 16 are laminated so that leading portions 16a are alternately exposed to the lateral surface 4c or 4d of the laminated body 4. At the leading portions 16a, the internal electrode layers 16 are electrically connected with the first external electrode 6 or the second external electrode 8.

In the present embodiment, the piezoelectric layers 10 at a central part of the laminated body 4 have piezoelectric active parts 12 sandwiched by the internal electrode layers 16. That is, the piezoelectric active parts 12 are a region surrounded by the dotted line shown in FIG. 2 and FIG. 3. In this region, a mechanical displacement is caused by voltage application via the first external electrode 6 and the second external electrode 8 having different polarities.

The internal electrode layers 16 are composed of any conductive material, such as a noble metal (e.g., Ag, Pd, Au, Pt), an alloy of these metals (e.g., Ag—Pd), a base metal (e.g., Cu, Ni), and an alloy of these metals, but are preferably composed of Ag—Pd alloy, Ag, Cu, or the like.

The first external electrode 6 and the second external electrode 8 are also composed of a conductive material, such as a material similar to the conductive material constituting the internal electrodes. The first external electrode 6 and the second external electrode 8 may be formed by mixing a conductive metal powder (e.g., Ag, Cu) and a glass powder (e.g., SiO₂) and firing this mixture. Incidentally, a plating layer or a sputtered layer containing the above-mentioned various metals may further be formed on the exteriors of the first external electrode 6 and the second external electrode 8.

The piezoelectric layers 10 are made of any material that exhibits piezoelectric effect or inverse piezoelectric effect, such as PbZrₓTi_{z-x}O₃ (PZT), BaTiO₃ (BT), BiNaTiO₃ (BNT), BiFeO₃ (BFO), (Bi₂O₂)²⁺(Aₘ₋₁BₘO₃ₘ₊₁)²⁻ (BLSF), and (K, Na)NbO₃ (KNN). To improve characteristics, the piezoelectric layers 10 may contain a sub-component. The amount of the sub-component is determined based on desired characteristics.

Incidentally, the piezoelectric layers 10 have any thickness, but preferably have a thickness of about 0.5 to 100 μm in the present embodiment. Likewise, the internal electrode layers 16 have any thickness, but preferably have a thickness of about 0.5 to 2.0 μm. As shown in FIG. 2 and FIG. 3, the piezoelectric layers 10 are arranged on the front surface 4a and the back surface 4b of the laminated body 4.

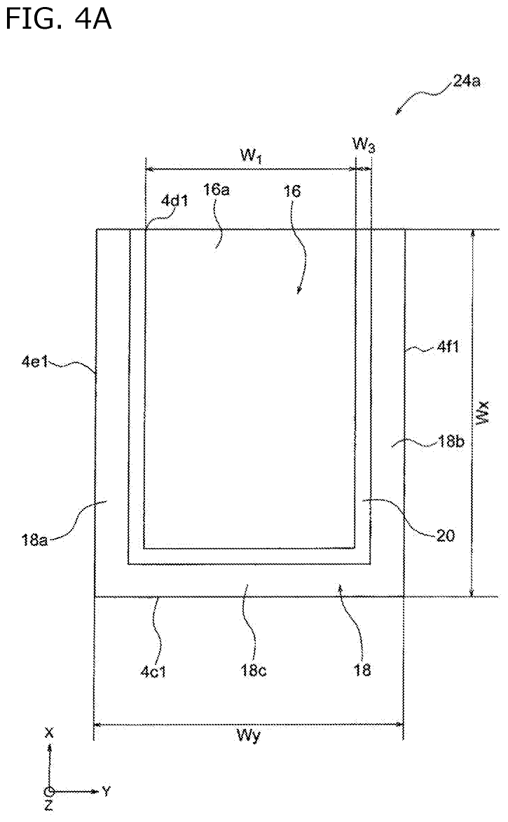

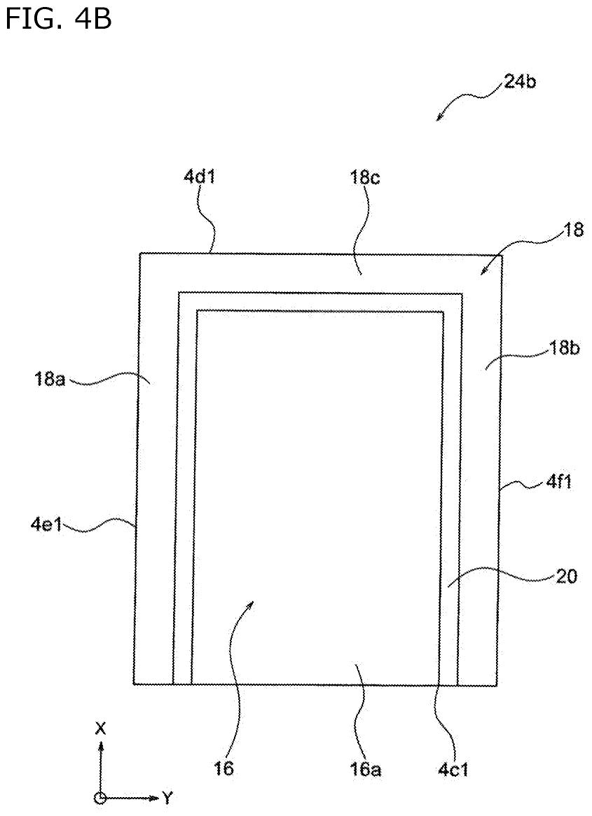

FIG. 4A is a schematic plane view of a first electrode pattern 24a contained in the laminated body 4. The piezoelectric layers 10 are located along a plane including the X-axis and the Y-axis at the lower side of the Z-axis direction shown in FIG. 4A. Each of the piezoelectric layers 10 has sides 4c1 to 4f1 corresponding to the lateral surfaces 4c to 4f of the laminated body 4 (see FIG. 1). Then, the first electrode pattern 24a formed from the internal electrode layer 16 and a dummy electrode layer 18 is laminated on the surface of the piezoelectric layer 10.

In the first electrode pattern 24a shown in FIG. 4A, the internal electrode layer 16 has the leading portion 16a exposed to the side 4d1. The dummy electrode layer 18 is formed with a gap 20 to surround the internal electrode layer 16 excluding the leading portion 16a. Thus, the internal electrode layer 16 and the dummy electrode layer 18 are insulated electrically.

In the present embodiment, the outer circumference of the dummy electrode layer 18 is exposed to the lateral surfaces 4c to 4f of the laminated body 4 and has a first lateral pattern 18a along the side 4e1, a second lateral pattern 18b along the side 4f1, and a joint pattern 18c along the side 4c1. The joint pattern 18c is located opposite to the leading portion 16a and joints the two lateral patterns 18a and 18b.

In the present embodiment, the first lateral part 6a of the first external electrode 6 is formed to have a width that is equal to or smaller than a width W1 of the internal electrode layers 16 in the Y-axis direction, and the dummy electrode layer 18 and the first lateral part 6a are not connected with each other. That is, the dummy electrode layer 18 is electrically insulated with the internal electrode layer 16 and the first external electrode 6 and does not contribute to appearance of piezoelectric characteristics. Since the dummy electrode layer 18 is formed in such a manner, the first external electrode 6 and the second external electrode 8 are not short-circuited via the dummy electrode layer 18.

To secure the electric insulation between the first external electrode 6 and the second external electrode 8, a slit may be formed on the lateral pattern 18a (18b) of the dummy electrode layer 18, or the dummy electrode layer 18 may be formed so that the end of the lateral pattern 18a (18b) is not exposed to the side 4d1. In this case, the first lateral part 6a of the first external electrode 6 can have a width that is equal to a width Wy of the piezoelectric layers 10 in the Y-axis direction.

In the present embodiment, the dummy electrode layer 18 is made of a material whose thermal shrinkage behavior is different from that of the internal electrode layers 16. Even though this material has a thermal shrink behavior differing from that of the internal electrode layers 16, the difference in thermal shrink behavior between the dummy electrode layers 18 and the internal electrode layers 16 needs to be smaller than that between the piezoelectric layers 10 and the internal electrode layers 16. Thus, the dummy electrode layer 18 preferably contains a conductive metal.

Specifically, when the internal electrode layers 16 are composed of an Ag—Pd alloy, the dummy electrode layer 18 is composed of an Ag—Pd alloy whose Pd content is larger than that of the internal electrode layers 16. When the internal electrode layers 16 are composed of Ag or Cu, the dummy electrode layer 18 is composed of Ag—Pd alloy or Ni.

Incidentally, “thermal shrinkage behavior is different” specifically means that the thermal shrinkage start temperature of the material constituting the dummy electrode layer 18 is higher than that of the conductive metal constituting the internal electrode layers 16. This effect is explained below in detail, but when the thermal shrinkage start temperature of the dummy electrode layer 18 is higher than that of the internal electrode layers 16, the number of sintered spots inside the laminated body 4 can be reduced.

The width W3 of the gap 20 shown in FIG. 4A is determined so that the internal electrode layer 16 and the dummy electrode layer 18 are not contacted with each other and is preferably 0.03 to 0.6 mm (more preferably, 0.05 to 0.3 mm) in the present embodiment. In this range, the insulating distance between the internal electrode layer 16 and the dummy electrode layer 18 can sufficiently be secured, and the dummy electrode layer 18 can sufficiently be functioned.

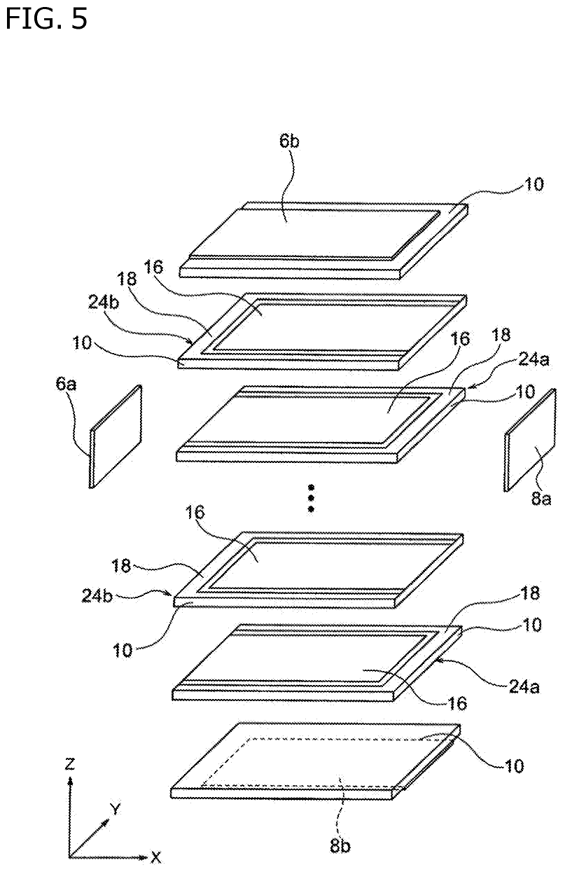

FIG. 5 is an exploded perspective view of the multilayer piezoelectric element 2 according to the present embodiment. When the piezoelectric layers 10 are laminated by three or more layers as shown in FIG. 5, the first electrode patterns 24a and the second electrode patterns 24b need to be laminated alternately. FIG. 4B shows a schematic plane view of the second electrode pattern 24b.

The second electrode pattern 24b has a form where the first electrode pattern 24a is rotated by 180 degrees around the Z-axis. That is, in the second electrode pattern 24b, the leading portion 16a of the internal electrode layer 16 is exposed to the side 4c1, and the joint pattern 18c of the dummy electrode layer 18 is exposed to the side 4d1. Except for these configurations, the second electrode pattern 24b is the same as the first electrode pattern 24a.

When a plurality of piezoelectric layers 10 and electrode patterns 24a and 24b is laminated as shown in FIG. 5, the displacement amount, the driving force, and the like can be increased compared to those of non-multilayer piezoelectric elements. In the present embodiment, the lamination number of piezoelectric layers 10 is two or more and has no upper limit, but is preferably about 3 to 20. The lamination number of piezoelectric layers 10 is appropriately determined based on the purpose of the multilayer piezoelectric element 2.

The multilayer piezoelectric element 2 according to the present embodiment is manufactured by any method and is, for example, manufactured by the following method.

First of all, a manufacturing step of the laminated body 4 is explained. In the manufacturing step of the laminated body 4, prepared are ceramic green sheets that will be the piezoelectric layers 10 after firing and a conductive paste that will be the internal electrode layers 16 and the dummy electrode layers 18 after firing.

For example, the ceramic green sheets are manufactured by the following manner. First of all, a raw material of a material constituting the piezoelectric layers 10 is mixed uniformly by wet mixing or so and is dried. Then, the raw material is calcined with appropriately determined conditions, and this calcined powder is pulverized in wet manner. The pulverized calcined powder is added with a binder and turned into a slurry. Then, the slurry is turned into a sheet by doctor blade method, screen printing method, or the like and is thereafter dried to obtain a ceramic green sheet. Incidentally, the raw material of the material constituting the piezoelectric layers 10 may contain inevitable impurities.

An internal electrode paste film constituting the electrode patterns 24 and a dummy electrode paste film are formed by printing method or so on the ceramic green sheet thus obtained. In the present embodiment, since the internal electrode layers 16 and the dummy electrode layers 18 are composed of materials having different thermal shrinkage behaviors, prepared are a paste for internal electrodes and a paste for dummy electrodes each containing different conductive materials. Then, the internal-electrode paste is initially printed on the ceramic green sheet in a predetermined pattern, and the dummy-electrode paste is thereafter (or previously) printed in a predetermined pattern. A desired electrode pattern can be formed by separately printing the internal electrode paste film and the dummy electrode paste film.

Next, the green sheets prepared in the above-mentioned procedure are laminated in a predetermined order. That is, the green sheets on which the first electrode pattern 24a is printed and the green sheets on which the second electrode pattern 24b is printed are laminated alternately. In the portion constituting the front surface 4a of the laminated body 4 after firing, only the ceramic green sheets are laminated.

Moreover, the laminated green sheets are pressurized for pressure bonding and are fired to obtain the laminated body 4 via necessary steps (e.g., drying step, debindering step). When the internal electrode layers are composed of a noble metal (e.g., Ag, Ag—Pd alloy), the firing is preferably carried out at a furnace temperature of 800-1200° C. and atmospheric pressure. When the internal electrode layers are composed of a base metal (e.g., Cu, Ni), the firing is preferably carried out at a furnace temperature of 800 to 1200° C. and an oxygen partial pressure of 1×10⁻⁷ to 1×10⁻⁹ MPa. When the laminated body is sintered in the firing step, volume shrinkage is generated in the piezoelectric layers and the electrode layers (the internal electrode layers and the dummy electrode layers).

External electrodes are formed on the laminated body 4 obtained through the above steps. The external electrodes are formed by sputtering, vapor deposition, plating, dip coating, or the like. The first external electrode 6 is formed on the front surface 4a and the lateral surface 4d of the laminated body 4, and the second external electrode 8 is formed on the back surface 4b and the lateral surface 4c of the laminated body 4. Incidentally, an insulation layer may be formed by applying an insulating resin onto the lateral surfaces 4d-4f of the laminated body 4 on which the external electrodes 6 and 8 are not formed.

After the external electrodes are formed, a polarization treatment is carried out for allowing the piezoelectric layers 10 to have piezoelectric activity. The polarization treatment is carried out by applying a DC electric field of 1-10 kV/mm to the first and second external electrodes 6 and 8 in an insulating oil of about 80 to 120 degrees. Incidentally, the DC electric field to be applied depends upon the material constituting the piezoelectric layers 10. Through such a process, the multilayer piezoelectric element 2 shown in FIG. 1 is obtained.

In the above process, the procedure for obtaining one multilayer piezoelectric element is shown, but actually used are green sheets on which multiple electrode patterns 24 are formed on one sheet. An aggregate laminate formed using such sheets is appropriately cut before or after firing and thereby finally has the shape of the element as shown in FIG. 1.

In the multilayer piezoelectric element 2 according to the present embodiment, as mentioned above, the dummy electrode layer 18 is formed along the outer circumference of the internal electrode layer 16 and is composed of a material whose thermal shrinkage start temperature is higher than that of the internal electrode layer 16. In the firing step, heat is easy to transmit in the vicinity of the outer circumference of the laminated body 4 (the dummy electrode layer 18 is formed). On the contrary, in the firing step, heat is hard to transmit in the central part of the internal electrode layers 16 (i.e., the central part of the laminated body 4). In the present embodiment, the dummy electrode layers 18 and the internal electrode layers 16 are made of different materials in accordance with the tendency of heat conduction in the sintering step.

In the present embodiment, the sintering behaviors of the electrode layers 16 and 18 are substantially adjusted by selecting different materials of the internal electrode layers 16 and the dummy electrode layer 18 in accordance with the tendency of heat conduction in the sintering step. In the multilayer piezoelectric element 2 according to the present embodiment, it is thereby possible to reduce the number of sintered spots between the outer circumference and the inside of the laminated body 4 and to restrain the generation of inner stress by the sintered spots. Since internal stress is weakened, the present embodiment can remarkably prevent the deformation of the laminated body 4 and the generation of cracks even if the piezoelectric layers 10 are thin, the lamination number of piezoelectric layers 10 is large, the lamination area of the laminated body 4 is wide and large, or the like.

In the present embodiment, there is no limit to the thickness and the lamination number of the piezoelectric layers 10 or to the size of the laminated body 4, but the following case is effectively applicable. The laminated body 4 is easily deformable if the piezoelectric layers 10 are thin, but the present embodiment can obtain the laminated body 4 having a good flatness even if the piezoelectric layers 10 have a thickness of 1-50 μm. Likewise, the present embodiment can obtain the laminated body 4 having a good flatness even if the lamination number of piezoelectric layers 10 is large (e.g., 3-20 layers). Moreover, the present embodiment can obtain the laminated body 4 having a good flatness even if the piezoelectric layers 10 have a large area of 100 (Wx) mm×100 (Wy) mm or more.

In the present embodiment, the dummy electrode layers 18 are preferably made of a material whose thermal shrinkage start temperature is higher than that of the conductive metal constituting the internal electrode layers 16 by 50° C. or higher and 280° C. or lower (more preferably, 70° C. or higher and 210° C. or lower). When the difference in thermal shrinkage start temperature is in the above range, it is possible to prevent cracks inside the laminated body and to obtain the laminated body 4 having a good flatness.

Incidentally, the thermal shrinkage start temperature of the material constituting each of the electrode layers 16 and 18 depends upon the composition of each of the electrode layers 16 and 18. Thus, the thermal shrinkage start temperature is determined by observing a cross section of the multilayer piezoelectric element with FE-SEM or so and measuring the composition of each of the electrode layers 16 and 18.

Then, a specific value of the thermal shrinkage start temperature is measured by preparing a paste sample based on the composition of each of the electrode layers 16 and 18 confirmed by the observation of the cross section and subjecting the paste sample to a thermomechanical analysis (TMA). More specifically, samples for the TMA are manufactured and measured for shrinkage factor by the TMA in the following manner.

First of all, a paste sample based on the composition of each of the electrode layers 16 and 18 is dried at 100° C. for 24 hours, and the dried sample is pulverized in an agate mortar. After that, the pulverized powder sample is pressed by a press machine and turned into a cylindrical green compact (3 mm in diameter, 5 mm in height). This green compact is debindered by heating at 350° C. for 5 hours and turned into a solid sample for TMA. The sample manufactured in such a manner is heated to 1000° C. at 300° C./h (heating rate), and the shrinkage factor of this sample at this time is measured by TMA.

In the present invention, the specific value of the thermal shrinkage start temperature is a temperature where the height of the sample is shrunk from the initial state by 2% or more in the above-mentioned TMA measurement. Incidentally, when the internal electrode layers 16 or the dummy electrode layers 18 are composed of a noble metal of Ag, Ag—Pd alloy, etc., the TMA measurement is carried out in an air atmosphere. Meanwhile, when the internal electrode layers 16 or the dummy electrode layers 18 are composed of a base metal of Cu, Ni, etc., the TMA measurement is carried out in a nitrogen atmosphere.

### Second Embodiment

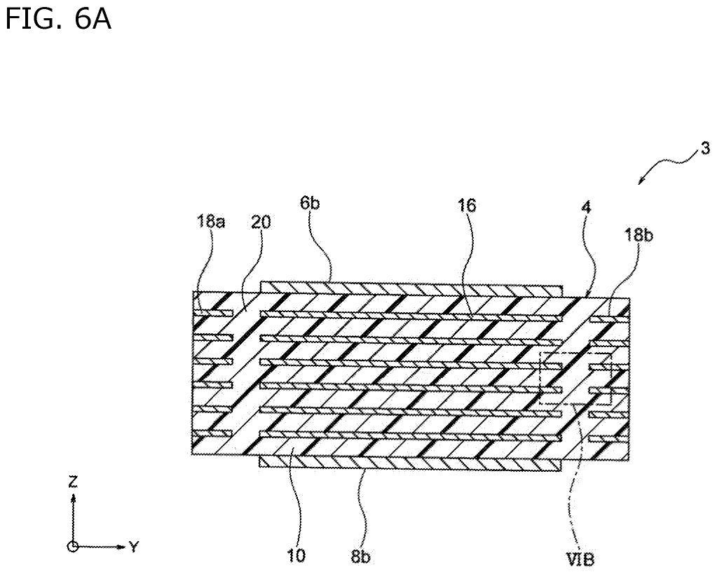

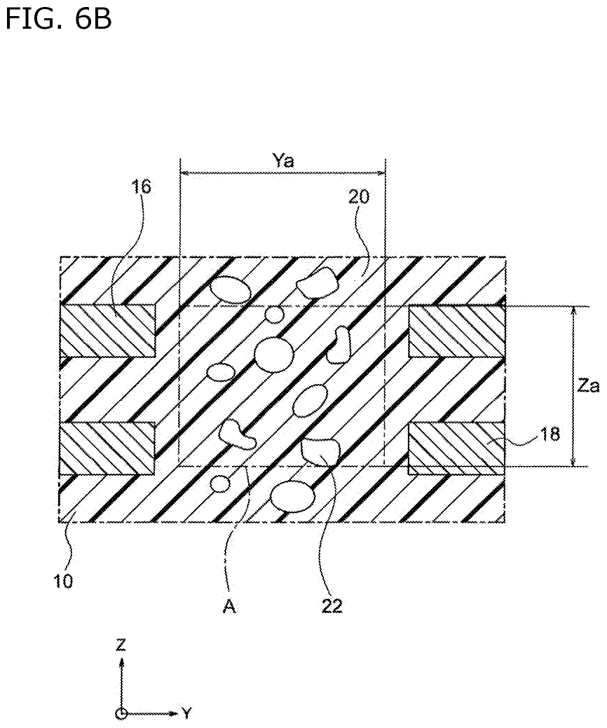

Hereinafter, Second Embodiment of the present invention is explained based on FIG. 6A and FIG. 6B. Incidentally, the common features between First Embodiment and Second Embodiment are not explained and are provided with the same references.

FIG. 6A is a schematic cross-sectional view of a multilayer piezoelectric element 3 according to Second Embodiment perpendicular to the X-axis direction. As shown in FIG. 6A, the laminated body 4 of the multilayer piezoelectric element 3 is formed from the piezoelectric layers 10, the internal electrode layers 16, and the dummy electrode layers 18. The composition and the multilayer structure of the piezoelectric layers 10, the internal electrode layers 16, and the dummy electrode layers 18 according to Second Embodiment are common with those of First Embodiment shown in FIG. 4A to FIG. 5.

FIG. 6B is an enlarged cross-sectional view of a main part of the region VIB shown FIG. 6A. In the laminated body 4 according to Second Embodiment shown in FIG. 6B, multiple pores 22 are formed in the piezoelectric layers 10 located in the gap 20 between the internal electrode layers 16 and the dummy electrode layers 18. The pores 22 are present to concentrate on a central part of the width (W3) of the gap 20 and are present in an inner central part of the laminated body 4 more than in the vicinity of the front surface 4a and the back surface 4b of the laminated body 4.

Although the effect demonstrated by the pores 22 is explained below in detail, the presence of the pores 22 reduces the inner stress of the laminated body 4 and makes it possible to prevent the change in composition of the piezoelectric layers 10.

Incidentally, the pores 22 can actually be measured by observing a cross section of the laminated body 4 with FE-SEM or so. In the present embodiment, a pore rate and a pore size of the pore 22 are defined in the following manner.

Before the pores 22 are analyzed, a cross section of the multilayer piezoelectric element 3 shown in FIG. 6A is observed with FE-SEM, and at least 10 analysis regions A are selected in an approximately central part in the gap 20. Here, “an approximately central part in the gap 20” means an approximately central position in the gap both in the Y-axis direction and in the Z-axis direction. Incidentally, the cross section for the analysis is a cross section that is approximately parallel to the short direction of the gap 20 (i.e., the direction of the gap width W3). For example, each of the analysis regions A has a width Za of about 0.05 mm and a width Ya of about 0.02 mm shown in FIG. 6B. A photograph of the cross section is taken in such a region.

The pore rate and the pore size are calculated by incorporating the above-taken cross-sectional pictures of the analysis regions A into a software for image analysis and determining the pores 22 with predetermined conditions using the software. At this time, the pore rate is calculated as a rate (Sh/Sa) of a total pore area Sh to an area Sa of the analysis region A. The pore size is obtained by converting an area of each of the pores 22 into a circle equivalent diameter. In the present embodiment, each of the pore rate and the pore size of the pores 22 is represented as an average of the 10 analysis regions A.

In Second Embodiment, the pores 22 preferably have a pore size of 0.05 μm or more and 0.2 μm or less, and the pores 22 preferably have a pore rate of 3% or more and 20% or less to a cross-sectional area of the gap 20. When the pores 22 have a pore size or a pore rate in the above-mentioned range, the deformation of the laminated body 4 and the generation of cracks can further appropriately be prevented.

The pores 22 are conceivably formed in such a manner that the internal electrode layers 16 and the dummy electrode layers 18 mutually pull the piezoelectric layers 10 in the process of the volume shrinkage of the electrode layers 16 and 18 in the firing step. Incidentally, for example, the pore rate and the pore size are controlled by the following method.

The pore rate can be controlled by the heating rate in the firing step or the difference in thermal shrinkage start temperature of materials constituting the electrode layers 16 and 18. In the firing step, when the heating rate is low, the pores 22 are easily generated, and the pore rate tends to be high. On the other hand, when the heating rate is high, the pore rate tends to low. Incidentally, the heating rate during firing is preferably 200° C./h or more and 1500° C./h or less.

When there is a large difference in thermal shrinkage start temperature of materials constituting the electrode layers 16 and 18, the pores 22 are easily generated, and the pore rate is high. On the other hand, when there is a small difference in thermal shrinkage start temperature of materials constituting the electrode layers 16 and 18, the pore rate tends to be low. As with First Embodiment, the difference in thermal shrinkage start temperature is preferably 50° C. or higher and 280° C. or lower (more preferably, 70° C. or higher and 210° C. or lower).

The pore size can be controlled by the holding time in the firing step or the difference in thermal shrinkage start temperature between the internal electrode layers 16 and the dummy electrode layers 18. When the holding time is long in the firing step, the pores 22 are united and grow and tend to have a large pore size. On the other hand, when the holding time is short, the pore size tends to be small. Incidentally, the holding time during firing is preferably 1 minute or longer and 240 minutes or shorter (more preferably, 15 minutes or longer and 120 minutes or shorter).

As with the pore rate, when there is a large difference in thermal shrinkage start temperature of materials constituting the electrode layers 16 and 18, the pore size is large. On the other hand, when there is a small difference in thermal shrinkage start temperature of materials constituting the electrode layers 16 and 18, the pore size tends to be small.

As mentioned above, the multilayer piezoelectric element 3 according to Second Embodiment have multiple pores 22 generated in the piezoelectric layer 10 located in the gap 20 in the heating process of the firing step. Since the electrode layers (the internal electrode layers 16 and the dummy electrode layers 18) are not laminated in the piezoelectric layers 10 located in the gap 20, the piezoelectric layer 10 located in the gap 20 is easy to become weak and to be affected by inner stress compared to the piezoelectric active parts 12 on which the electrode layers are laminated.

In Second Embodiment, multiple pores 22 are formed in the heating process, and the piezoelectric layer 10 located in the gap 20 thereby has elasticity and flexibility. That is, the pores 22 conceivably reduce the inner stress and the difference in flexibility between the piezoelectric active parts 12 and the inactive parts in manufacturing or using the multilayer piezoelectric element 3. In Second Embodiment, it is thereby possible to remarkably prevent the deformation of the laminated body 4 and the generation of cracks even if the piezoelectric layers 10 are thin, the lamination number of piezoelectric layers 10 is large, the lamination area of the laminated body 4 is wide and large, or the like

In the multilayer piezoelectric element 3 according to Second Embodiment, the presence of multiple pores 22 can prevent the composition of the piezoelectric layers 10 from changing. Piezoelectric ceramics constituting the piezoelectric layers 10 often contain elements of Pb, Bi, K, Na, etc. These elements are easily volatilized in the firing step and discharged to the outside of the laminated body 4. Thus, the composition of the piezoelectric layers 10 changes from the intended composition. In Second Embodiment, the pores 22 conceivably stay the volatilized elements inside the laminated body 4. Thus, the composition of the piezoelectric layers 10 is hard to change, and the multilayer piezoelectric element 3 having a high piezoelectric constant is obtained.

In Second Embodiment, the gap 20 preferably has a width W3 of 0.05 mm or larger and 0.3 mm or smaller (more preferably, 0.1 mm or larger and 0.3 mm or smaller). When the gap 20 has such a width, a region where the pores 22 are present is in an appropriate range, and the above-mentioned function of the pores 22 can sufficiently be secured.

The present invention is not limited to the above-mentioned embodiments and can variously be changed within the scope of the present invention. For example, the multilayer piezoelectric element 2 (3) has a substantially rectangular plan-view shape in the above-mentioned embodiments, but may have any other plan-view shape of circle, ellipse, polygon, etc. The electrode pattern 24a shown in FIG. 4A and an electrode pattern (not shown) failing to have the dummy electrode layer 18 may be laminated alternately.

The multilayer piezoelectric element according to the present invention can be utilized as a conversion element from electrical energy to mechanical energy. For example, the multilayer piezoelectric element according to the present invention is applicable to piezoelectric actuators, piezoelectric buzzers, piezoelectric sounders, ultrasonic motors, speakers, etc. and is particularly favorably utilized as piezoelectric actuators. Specifically, the piezoelectric actuators are utilized for haptic devices, lens driving, HDD head driving, inkjet printer head driving, fuel injection valve driving, etc.

### EXAMPLES

Hereinafter, the present invention is explained based on further detailed examples, but is not limited thereto.

### (Experiment 1)

First of all, predetermined amounts of chemically pure main-component raw material and sub-component raw material were weighed so that piezoelectric layers would be composed of PZT based ceramics, and the raw materials were mixed in wet manner in a ball mill. After the mixing, the mixture was calcined at 800° C. to 900° C. and pulverized again in the ball mill. The calcined powder thus obtained was added with a binder and turned into a slurry. The slurry was turned into a sheet by screen printing method and thereafter dried to obtain ceramic green sheets.

Next, a conductive paste for internal electrodes was applied onto the ceramic green sheets by printing method, and a conductive paste for dummy electrodes was further applied thereonto. At this time, an electrode pattern was printed so that the gap width (W3) between the internal electrode layer and the dummy electrode layer would be 0.3 mm on average by adjusting application positions of the conductive pastes.

After the green sheets thus obtained were laminated by nine or more layers in a predetermined order, the laminated green sheets were pressed to be bonded and were dried and debindered. In Experiment 1, samples of laminate bodies were obtained by carrying out a firing treatment at 1500° C./h (heating rate), 15 minutes (holding time), and 1000° C. (holding temperature).

In the preparation of the samples of laminated bodies, the conductive pastes were changed in each Example. Table 1 shows the compositions of the internal electrode layers and the dummy electrode layers formed in each Example. The values of the composition cells in Table 1 mean the amount of each element in the alloy. Thus, for example, “Ag90-Pd10” means an Ag—Pd alloy containing 90 wt % of Ag and 10 wt % of Pd.

In Experiment 1, an experiment was carried out by changing the standard of the difference in thermal shrinkage start temperature of materials constituting the respective electrode layers, and the samples of laminated bodies of Examples 1-10 were obtained.

Incidentally, the fired laminated bodies of Experiment 1 had a substantially rectangular parallelepiped shape of width (Wx) 30 mm×length (Wy) 30 mm×thickness 0.1 mm. The thickness of the piezoelectric layers was 10 μm on average. The thickness of the internal electrode layers was 1 μm on average. The laminated bodies thus manufactured were provided with a pair of external electrodes and were polarized, and samples of multilayer piezoelectric elements were thereby manufactured. In each Example, 1000 samples were manufactured and subjected to the following evaluation.

### Comparative Example 1

Except for forming no dummy electrode layers, the structure of Comparative Example 1 was equal to that of Examples 1-10.

### Comparative Example 2

In Comparative Example 2, the dummy electrode layers were formed, but made of the same material as the conductive metal constituting the internal electrode layers. That is, the difference in thermal shrinkage start temperature was 0° C. in Comparative Example 2. Except for this structure, samples of multilayer piezoelectric elements according to Comparative Example 2 were manufactured similarly to Examples 1-10.

### Comparative Example 3

Comparative Example 3 was samples of multilayer piezoelectric elements corresponding to Patent Document 1 (JP2014072357 (A)). That is, in Comparative Example 3, no dummy electrode layers were formed, and the palladium content of the Ag—Pd alloy was configured to increase gradually from the inner center to the outer side of the internal electrode layers. The specific composition of the internal electrode layers was Ag90 wt %-Pd10 wt % at the inner center and Ag70 wt %-Pd30 wt % at the outer side. Other configurations were similar to those of Examples 1-10, and samples of multilayer piezoelectric elements according to Comparative Example 3 were manufactured.

### (Evaluation)

### Measurement of Flatness

The flatness of each Comparative Example and each Example was measured using a CNC image measuring machine (NEXIV VMZ-R6555 manufactured by NIKON INSTECH CO., LTD.). The flatness was measured by making a least-square plane based on height data obtained by irradiating the laminated bodies with laser light and calculating a maximum height and a minimum height with the least-square plane as the reference plane. The flatness is represented by the maximum height−the minimum height. The smaller the flatness is, the less the laminated bodies are deformed. Incidentally, the measurement was carried out 900 times in each Example, and this average was obtained as a measurement result and is shown in Table 1. Incidentally, the target value of the flatness was 200 μm or less.

Measurement of Piezoelectric Constant d_{×}

A piezoelectric constant d₃₃ (piezoelectric output constant) of each comparative example and each example was measured by Berlincourt method using a d₃₃ meter. The piezoelectric constant d₃₃ is calculated by measuring an electric charge generated in the element body in application of vibration to the piezoelectric element. When the main component of the piezoelectric layers is PZT, a piezoelectric constant d₃₃ of 400×10⁻¹² C/N or more is considered to be favorable. When the main component of the piezoelectric layers is BFO-BT, a piezoelectric constant d₃₃ of 200×10¹² C/N or more is considered to be favorable. When the main component of the piezoelectric layers is KNN, a piezoelectric constant d₃₃ of 250×10¹² C/N or more is considered to be favorable. The measurement result of each example is shown in Table 1.

### Evaluation of Cracks

Cracks were evaluated by observing cross sections of the manufactured samples of laminated bodies by FE-SEM. Specifically, a crack incidence was calculated in the following manner. First of all, 100 samples were selected at random from 1000 samples of laminated bodies and fixed on a resin, and a cross section of the 100 samples underwent a mirror polishing. Then, a crack incidence was calculated by counting samples having a crack of the piezoelectric layers, a peeling between the piezoelectric layers and the electrode layers, or the like in the observation of the cross section of each sample. In terms of the crack incidence, 18% or less was considered to be pass/fail criteria, 15% or less was more favorable, and 10% or less was considered to be still more favorable. The measurement result of each example is shown in Table 1.

TABLE 1

| | | Internal Electrode Layers | | Dummy Electrode Layers | | Difference in | | | | | | |
|---|---|---|---|---|---|---|---|---|---|---|---|---|
| | | | Thermal | | Thermal | Thermal | | | | | | Piezo- |
| | | | Shrinkage | | Shrinkage | Shrinkage | Firing Conditions | | | | | electric |
| | Piezo- | | Start | | Start | Start | | | Holding | Crack | | Constant |
| | electric | | Tem- | | Tem- | Tem- | Heating | Holding | Tem- | Inci- | Flat- | d₃₃ |
| Sample | Compo- | Compo- | perature | Compo- | perature | perature | Rate | Time | perature | dence | ness | (×10⁻¹² |
| No. | sition | sition | ° C. (A) | sition | ° C. (B) | (B) − (A) | (° C./h) | (min) | (° C.) | (%) | (μm) | C/N) |
| Comp. | PZT | Ag90—Pd10 | — | — | — | — | 1500 | 15 | 1000 | 37 | 533 | 387 |
| Ex. 1 | | | | | | | | | | | | |
| Comp. | PZT | Ag90—Pd10 | 470 | Ag90—Pd10 | 470 | 0 | 1500 | 15 | 1000 | 22 | 245 | 390 |
| Ex. 2 | | | | | | | | | | | | |
| Ex. 1 | PZT | Cu100 | 340 | Ag95—Pd5 | 380 | 40 | 1500 | 15 | 1000 | 14 | 208 | 442 |
| Ex. 2 | PZT | Ag100 | 330 | Ag95—Pd5 | 380 | 50 | 1500 | 15 | 1000 | 9 | 143 | 465 |
| Ex. 3 | PZT | Ag90—Pd10 | 470 | Ag80—Pd20 | 540 | 70 | 1500 | 15 | 1000 | 7 | 158 | 480 |
| Ex. 4 | PZT | Cu100 | 340 | Ni100 | 430 | 90 | 1500 | 15 | 1000 | 8 | 131 | 470 |
| Ex. 5 | PZT | Ag100 | 330 | Ni100 | 430 | 100 | 1500 | 15 | 1000 | 5 | 141 | 464 |
| Ex. 6 | PZT | Ag100 | 330 | Ag90—Pd10 | 470 | 140 | 1500 | 15 | 1000 | 5 | 156 | 469 |
| Ex. 8 | PZT | Ag100 | 330 | Ag80—Pd20 | 540 | 210 | 1500 | 15 | 1000 | 9 | 177 | 472 |
| Ex. 9 | PZT | Ag100 | 330 | Ag70—Pd30 | 610 | 280 | 1500 | 15 | 1000 | 12 | 198 | 455 |
| Ex. 10 | PZT | Ag100 | 330 | Ag65—Pd35 | 700 | 370 | 1500 | 15 | 1000 | 15 | 217 | 432 |
| Comp. | PZT | Ag90—Pd10 | — | — | — | — | 1500 | 15 | 1000 | 35 | 225 | 391 |
| Ex. 3 | | to | | | | | | | | | | |
| | | Ag70—Pd30 | | | | | | | | | | |

### Evaluation 1

As shown in Table 1, compared to Comparative Examples 1 and 2, Examples 1-10 had a small flatness and further had a low crack incidence. Thus, when the thermal shrinkage start temperature of the material constituting the dummy electrode layers was higher than that of the internal electrode layers, the deformation of the laminated body and the generation of cracks were prevented.

In particular, Examples 2-9 had a crack incidence of 15% or less and a flatness of 200 μm or less, and both of these satisfied an optimal standard value. Meanwhile, Example 1 and Example 10 had a flatness that was better than that of Comparative Examples but was larger than that of the other examples. As a result of Example 1, when the difference in thermal shrinkage start temperature between the internal electrode layers and the dummy electrode layers was 50° C. or higher, the sintered spots were sufficiently reduced, and it was more effective.

As a result of Example 10, it is conceivable that when the thermal shrinkage behaviors were too different from each other between the internal electrode layers and the dummy electrode layers, the flatness was rather bad due to stress generated inside the laminated body. Based on the above-mentioned results, it was confirmed that there was an appropriate range for the difference in thermal shrinkage start temperature between the internal electrode layers and the dummy electrode layers, and that particularly favorable characteristics were obtained if the difference was 50° C.−280° C. It was also confirmed that Examples 3-8 (the difference in thermal shrinkage start temperature was 70° C.−210° C.) had a crack incidence of 10% or less and were particularly favorable for preventing cracks of the laminated body.

Incidentally, the crack incidence of Comparative Example 3 was higher than that of each Example. It is conceivable that, like Comparative Example 3, when the Pd content of the internal electrode layers was changed, cracks were generated due to bad bonding strength between the internal electrode layers and the piezoelectric layers. Accordingly, the superiority of the present invention was proved.

### (Experiment 2)

After the internal electrode layers and the dummy electrode layers were composed of Ag—Pd alloys having different compositions, Experiment 2 was carried out with different conditions of the sintering step, and multiple samples of multilayer piezoelectric elements having pores in the gap were manufactured. Table 2 shows the structure and the results of pore size and pore rate of each Example. Incidentally, the pore size and the pore rate were measured using an image analysis type particle size distribution measurement software (Mac-View). The features other than those written in Table 2 were common with those of each Example of Experiment 1.

Incidentally, the materials constituting the piezoelectric layers were different from each other in Examples 23 and 24 of Experiment 2. Bismuth ferrate-barium titanate (BFO-BT) was used in Example 23, and potassium sodium niobite (KNN) was used in Example 24. When the main component was BFO-BT, a piezoelectric constant d₃₃ of 200×10¹² C/N or more was considered to be favorable. When the main component was KNN, a piezoelectric constant d₃₃ of 250×10¹² C/N or more was considered to be favorable.

In Examples 25-36 of Experiment 2, an experiment was carried out by also changing the gap width standard, and samples of multilayer piezoelectric elements were manufactured. The detailed features are shown in Table 2.

### Comparative Examples 4 and 5

Except for changing the material constituting the piezoelectric layers, samples of multilayer piezoelectric elements according to Comparative Examples 4 and 5 were manufactured similarly to Comparative Example 1.

### Comparative Example 6

In Comparative Example 6, no dummy electrode layers were formed, and no pores were formed inside the laminated body. Instead, in Comparative Example 6, burned particles were contained in the raw material of the external electrodes in forming them, and pores were formed in the external electrodes. The detailed features of Comparative Example 6 are shown in Table 2.

TABLE 2

| | | Internal Electrode Layers | | Dummy Electrode Layers | | Difference in | | | | | | |
|---|---|---|---|---|---|---|---|---|---|---|---|---|
| | | | Thermal | | Thermal | Thermal | | | | | | |
| | | | Shrinkage | | Shrinkage | Shrinkage | Firing Conditions | | | | Pores | |
| | Piezo- | | Start | | Start | Start | | | Holding | | in Gap | |
| | electric | | Tem- | | Tem- | Tem- | Heating | Holding | Tem- | Gap | Pore | Pore |
| Sample | Compo- | Compo- | perature | Compo- | perature | perature | Rate | Time | perature | Width | Rate | Size |
| No. | sition | sition | ° C. (A) | sition | ° C. (B) | (B) − (A) | (° C./h) | (min) | (° C.) | (mm) | (%) | (nm) |
| Comp. | PZT | Ag90—Pd10 | 470 | — | — | — | 1500 | 15 | 1000 | — | — | — |
| Ex. 1 | | | | | | | | | | | | |
| Comp. | PZT | Ag90—Pd10 | 470 | Ag90—Pd10 | 470 | 0 | 1500 | 15 | 1000 | 0.3 | 0 | 0 |
| Ex. 2 | | | | | | | | | | | | |
| Ex. 12 | PZT | Ag90—Pd10 | 470 | Ag80—Pd20 | 540 | 70 | 1500 | 15 | 1000 | 0.3 | 5 | 52 |
| Ex. 13 | PZT | Ag90—Pd10 | 470 | Ag80—Pd20 | 540 | 70 | 1500 | 60 | 1000 | 0.3 | 7 | 119 |
| Ex. 14 | PZT | Ag90—Pd10 | 470 | Ag70—Pd30 | 610 | 140 | 1500 | 120 | 1000 | 0.3 | 8 | 180 |
| Ex. 15 | PZT | Ag90—Pd10 | 470 | Ag80—Pd20 | 540 | 70 | 600 | 15 | 1000 | 0.3 | 14 | 79 |
| Ex. 16 | PZT | Ag90—Pd10 | 470 | Ag80—Pd20 | 540 | 70 | 600 | 60 | 1000 | 0.3 | 15 | 120 |
| Ex. 17 | PZT | Ag90—Pd10 | 470 | Ag70—Pd30 | 610 | 140 | 600 | 120 | 1000 | 0.3 | 15 | 198 |
| Ex. 18 | PZT | Ag90—Pd10 | 470 | Ag80—Pd20 | 540 | 70 | 200 | 15 | 1000 | 0.3 | 18 | 95 |
| Ex. 19 | PZT | Ag90—Pd10 | 470 | Ag80—Pd20 | 540 | 70 | 200 | 60 | 1000 | 0.3 | 20 | 132 |
| Ex. 20 | PZT | Ag90—Pd10 | 470 | Ag70—Pd30 | 610 | 140 | 200 | 120 | 1000 | 0.3 | 20 | 165 |
| Ex. 21 | PZT | Ag90—Pd10 | 470 | Ag70—Pd30 | 610 | 140 | 1500 | 120 | 1050 | 0.1 | 12 | 224 |
| Ex. 22 | PZT | Ag90—Pd10 | 470 | Ag70—Pd30 | 610 | 140 | 200 | 15 | 1050 | 0.1 | 24 | 145 |
| Comp. | BFO-BT | Ag90—Pd10 | 470 | — | — | — | 1500 | 15 | 830 | — | — | — |
| Ex. 4 | | | | | | | | | | | | |
| Comp. | KNN | Ag90—Pd10 | 470 | — | — | — | 1500 | 15 | 930 | — | — | — |
| Ex. 5 | | | | | | | | | | | | |
| Ex. 23 | BFO-BT | Ag100 | 330 | Ag90—Pd10 | 470 | 140 | 1500 | 15 | 830 | 0.3 | 7 | 64 |
| Ex. 24 | KNN | Ag100 | 330 | Ag90—Pd10 | 470 | 140 | 1500 | 15 | 930 | 0.3 | 10 | 139 |
| Ex. 25 | PZT | Ag90—Pd10 | 470 | Ag80—Pd20 | 540 | 70 | 1500 | 15 | 1000 | 0.4 | 3 | 50 |
| Ex. 26 | PZT | Ag90—Pd10 | 470 | Ag70—Pd30 | 610 | 140 | 200 | 120 | 1000 | 0.4 | 13 | 123 |
| Ex. 27 | PZT | Ag90—Pd10 | 470 | Ag80—Pd20 | 540 | 70 | 1500 | 15 | 1000 | 0.3 | 5 | 52 |
| Ex. 28 | PZT | Ag90—Pd10 | 470 | Ag70—Pd30 | 610 | 140 | 200 | 120 | 1000 | 0.3 | 20 | 165 |
| Ex. 29 | PZT | Ag90—Pd10 | 470 | Ag80—Pd20 | 540 | 70 | 1500 | 15 | 1000 | 0.2 | 7 | 71 |
| Ex. 30 | PZT | Ag90—Pd10 | 470 | Ag70—Pd30 | 610 | 140 | 200 | 120 | 1000 | 0.2 | 20 | 188 |
| Ex. 31 | PZT | Ag90—Pd10 | 470 | Ag80—Pd20 | 540 | 70 | 1500 | 15 | 1000 | 0.1 | 8 | 67 |
| Ex. 32 | PZT | Ag90—Pd10 | 470 | Ag70—Pd30 | 610 | 140 | 200 | 120 | 1000 | 0.1 | 19 | 197 |
| Ex. 33 | PZT | Ag90—Pd10 | 470 | Ag80—Pd20 | 540 | 70 | 1500 | 15 | 1000 | 0.05 | 10 | 74 |
| Ex. 34 | PZT | Ag90—Pd10 | 470 | Ag70—Pd30 | 610 | 140 | 200 | 120 | 1000 | 0.05 | 15 | 165 |
| Ex. 35 | PZT | Ag90—Pd10 | 470 | Ag80—Pd20 | 540 | 70 | 1500 | 15 | 1000 | 0.03 | 4 | 55 |
| Ex. 36 | PZT | Ag90—Pd10 | 470 | Ag70—Pd30 | 610 | 140 | 200 | 120 | 1000 | 0.03 | 6 | 142 |
| Comp. | PZT | Ag90—Pd10 | 470 | — | — | — | 200 | 120 | 1000 | 0.3 | — | — |
| Ex. 6 | | | | | | | | | | | | |

### Evaluation 2-1

Based on the data of Examples 12-22 shown in Table 2, it was confirmed that when the heating rate in the firing step was slow, pores were easily generated in the gap, and the pore rate tended to be high. It was also confirmed that when the holding time in the firing step was long, pores were united and grew, and the pore size became large.

Incidentally, the pore rate and the pore size were also changed based on the holding temperature. In Example 23, the pore size was large (200 nm or more) because the holding temperature was 1050° C., which was higher than that of the other examples, and the firing time was long. In Example 24, the pore rate was high (20% or more) because the holding temperature was 1050° C. at the slow heating rate (200° C./h).

As with Experiment 1, each comparative example and each example according to Experiment 2 were subsequently measured for flatness and piezoelectric constant d₃₃ and evaluated for cracks. The results are shown in Table 3.

TABLE 3

| | | | | Crack | | Piezoelectric |
|---|---|---|---|---|---|---|
| | Gap | Pores in Gap | | Inci- | | Constant d₃₃ |
| Sample | Width | Pore Rate | Pore Size | dence | Flatness | (×10⁻¹² |
| No. | (mm) | (%) | (nm) | (%) | (μm) | C/N) |
| Comp. | — | — | — | 37 | 533 | 387 |
| Ex. 1 | | | | | | |
| Comp. | 0.3 | 0 | 0 | 22 | 245 | 395 |
| Ex. 2 | | | | | | |
| Ex. 12 | 0.3 | 5 | 52 | 7 | 158 | 480 |
| Ex. 13 | 0.3 | 7 | 119 | 2 | 132 | 471 |
| Ex. 14 | 0.3 | 8 | 180 | 2 | 115 | 457 |
| Ex. 15 | 0.3 | 14 | 79 | 2 | 155 | 481 |
| Ex. 16 | 0.3 | 15 | 120 | 8 | 144 | 475 |
| Ex. 17 | 0.3 | 15 | 198 | 7 | 130 | 462 |
| Ex. 18 | 0.3 | 18 | 95 | 8 | 169 | 470 |
| Ex. 19 | 0.3 | 20 | 132 | 7 | 143 | 462 |
| Ex. 20 | 0.3 | 20 | 165 | 7 | 129 | 453 |
| Ex. 21 | 0.1 | 12 | 224 | 17 | 112 | 439 |
| Ex. 22 | 0.1 | 24 | 145 | 18 | 102 | 452 |
| Comp. | — | — | — | 31 | 486 | 181 |
| Ex. 4 | | | | | | |
| Comp. | — | — | — | 38 | 561 | 244 |
| Ex. 5 | | | | | | |
| Ex. 23 | 0.3 | 7 | 64 | 2 | 94 | 230 |
| Ex. 24 | 0.3 | 10 | 139 | 8 | 148 | 295 |
| Ex. 25 | 0.4 | 3 | 50 | 6 | 209 | 443 |
| Ex. 26 | 0.4 | 13 | 123 | 8 | 203 | 433 |
| Ex. 27 | 0.3 | 5 | 52 | 7 | 158 | 480 |
| Ex. 28 | 0.3 | 20 | 165 | 7 | 129 | 453 |
| Ex. 29 | 0.2 | 7 | 71 | 4 | 167 | 485 |
| Ex. 30 | 0.2 | 20 | 188 | 7 | 111 | 464 |
| Ex. 31 | 0.1 | 8 | 67 | 6 | 153 | 489 |
| Ex. 32 | 0.1 | 19 | 197 | 7 | 88 | 442 |
| Ex. 33 | 0.05 | 10 | 74 | 12 | 139 | 430 |
| Ex. 34 | 0.05 | 15 | 165 | 14 | 80 | 434 |
| Ex. 35 | 0.03 | 4 | 55 | 18 | 101 | 419 |
| Ex. 36 | 0.03 | 6 | 142 | 17 | 70 | 412 |
| Comp. | 0.3 | — | — | 5 | 489 | 380 |
| Ex. 6 | | | | | | |

### Evaluation 2-2

According to Table 3, compared to Comparative Examples 1 and 2, Examples 12-22 (pores were formed) had a small flatness and also had a low crack incidence. Thus, when pores were formed in the gap, the deformation of the laminated body and the cracks inside the laminated body were prevented.

Compared to Comparative Examples 1 and 2, Examples 12-22 had a high piezoelectric constant d₃₃ satisfying the standard value. In Comparative Examples 1 and 2, the Pb element was volatilized to the outside of the laminated body during firing. In Examples 12-22, the existence of the pores conceivably prevents the volatilized element from flowing to the outside and achieves high piezoelectric characteristics.

In particular, the crack incidence was restrained to 10% or less in Examples 12-20 (pore rate: 3% to 20%, pore size: 50 nm to 200 nm). On the other hand, Example 21 (pore size: 200 nm or more) and Example 22 (pore rate: 20% or more) had a crack incidence of 15%-18%, which was higher than that of Examples 12-20. To prevent the deformation of the laminated body and the generation of cracks, it was particularly effective to have a pore rate or a pore size in the above-mentioned range. Incidentally, the flatness and the piezoelectric constant d₃₃ were also favorable in Examples 21 and 22 compared to those of Comparative Examples 1 and 2, and Examples 21 and 22 were superior to the comparative examples.

In comparison between Examples 23 and 24 and Comparative Examples 4 and 5, even if the composition of the piezoelectric layers is changed, the structure of the present invention can prevent cracks of the laminated body and achieve a multilayer piezoelectric element having favorable flatness and piezoelectric characteristics.

Next, Examples 25-36 (the standard of the gap width W3 was changed) were examined. In Examples 27-34 (gap width W3: 0.05 mm to 0.3 mm), the crack incidence was restrained to 15% or less, and the flatness was 200 μm or less. In particular, Examples 27-32 (gap width W3: 0.1 mm to 0.3 mm) had a crack incidence of 10% or less, and it was confirmed that this range of the gap width W3 was particularly favorable for preventing cracks of the laminated body.

On the other hand, Examples 25 and 26 (large gap width W3) had a high flatness compared to Examples 27-36 and exhibited a tendency where the flatness became worse if the gap width W3 became too large. Examples 35 and 36 (small gap width W3) had a good flatness, but had a high crack incidence compared to Examples 25-34. This is probably because if the gap width W3 is too small, the sintered spots can be reduced, but the region where pores are present becomes small, and the prevention effect on cracks by the pores becomes weak.

Incidentally, Comparative Example 6 can prevent the generation of cracks to some degree by also forming pores in the external electrodes. In Comparative Example 6, however, the flatness was worse than that of Examples of the present invention, and the laminated body was deformed during manufacture. Moreover, Comparative Example 6 had a low piezoelectric constant d₃₃ compared to Examples. As a result, the structure of the present invention with pores in the gap can achieve both deformation of the laminated body and prevention of cracks and is thereby superior compared to when pores are formed in external electrodes.

### DESCRIPTION OF THE REFERENCE NUMERICAL

2, 3 . . . multilayer piezoelectric element
4 . . . laminated body
4a . . . front surface of laminated body
4b . . . back surface of laminated body
4c-4f . . . lateral surface of laminated body
6 . . . first external electrode
6a . . . first lateral part
6b . . . first surface part
8 . . . second external electrode
8a . . . second lateral part
8b . . . second back part
10 . . . piezoelectric layer
12 . . . piezoelectric active part
16 . . . internal electrode layer
16a . . . leading portion
18 . . . dummy electrode layer
18a, 18b . . . lateral pattern
18c . . . joint pattern
20 . . . gap
22 . . . pore
24a, 24b . . . electrode pattern
4c1-4f1 . . . side

What is claimed is:

1. A multilayer piezoelectric element comprising:
a laminated body including:
a piezoelectric layer formed along a plane including a first axis and a second axis perpendicular to each other; and
an internal electrode layer laminated on the piezoelectric layer; and
a lateral electrode formed on a lateral surface of the laminated body perpendicular to the first axis,
wherein the internal electrode layer has a leading portion exposed to the lateral surface of the laminated body and is electrically connected with the lateral electrode via the leading portion,
wherein a dummy electrode layer is formed with a gap to surround the internal electrode layer excluding the leading portion on the plane of the piezoelectric layer, and
wherein the dummy electrode layer is composed of a material whose thermal shrinkage start temperature is higher than that of a conductive metal constituting the internal electrode layer.

2. The multilayer piezoelectric element according to claim 1, wherein the dummy electrode layer is composed of a conductive metal whose composition is different from that of the conductive metal constituting the internal electrode layer.

3. The multilayer piezoelectric element according to claim 1, wherein the dummy electrode layer is composed of a material whose thermal shrinkage start temperature is higher than that of the conductive metal constituting the internal electrode layer by 50° C. or more and 280° C. or less.

4. The multilayer piezoelectric element according to claim 1, wherein multiple pores are formed in the piezoelectric layer located in the gap between the internal electrode layer and the dummy electrode layer.

5. The multilayer piezoelectric element according to claim 4, wherein the pores have an average size of 0.05 μm or more and 0.2 μm or less.

6. The multilayer piezoelectric element according to claim 4, wherein the piezoelectric layer located in the gap has a pore rate of 3% or more and 20% or less.

7. The multilayer piezoelectric element according to claim 5, wherein the piezoelectric layer located in the gap has a pore rate of 3% or more and 20% or less.

8. The multilayer piezoelectric element according to claim 1, wherein the gap has a width of 0.05 mm or more and 0.3 mm or less.

9. The multilayer piezoelectric element according to claim 4, wherein the gap has a width of 0.05 mm or more and 0.3 mm or less.
